(19) United States
(12) Patent Application Publication
(10) Pub. No.: US 2011/0115006 A1
(43) Pub. Date: May 19, 2011

(54) SUBSTRATE FOR SEMICONDUCTOR DEVICE, METHOD FOR PRODUCING THE SAME, SEMICONDUCTOR DEVICE, AND ELECTRONIC APPARATUS

(75) Inventor: Takashi Sato, Chino-shi (JP)

(73) Assignee: Seiko Epson Corporation, Tokyo (JP)

(21) Appl. No.: 12/942,674

(22) Filed: Nov. 9, 2010

(30) Foreign Application Priority Data
Nov. 13, 2009 (JP) 2009-259951

(51) Int. Cl. H01L 27/06; H01L 21/20

(52) U.S. Cl. 257/296; 438/478; 257/E27.016; 257/E21.09

(57) ABSTRACT

A substrate for a semiconductor device includes a substrate; a transistor disposed on the substrate and including a semiconductor layer, a first insulating film provided in the form of islands so as to at least partly overlap with the semiconductor layer in plan view on the substrate, and a gate electrode disposed so as to face the semiconductor layer with the first insulating film therebetween; and a second insulating film that is disposed on the substrate as substantially the same film as the first insulating film and that is formed in the form of islands so that at least one of the material and the thickness of the second insulating film is different from that of the first insulating film.

### BACKGROUND

1. Technical Field

The present invention relates to technical fields of a substrate for a semiconductor device, a semiconductor device including the substrate, and an electronic apparatus including the semiconductor device.

2. Related Art

An example of this type of substrate for a semiconductor device is an active matrix substrate which is used in a display device such as an electrophoretic display device driven by an active-matrix driving method, and which includes pixel electrodes, scanning lines, data lines, and thin-film transistors (TFTs) functioning as pixel switching elements, the scanning lines, the data lines, and the TFTs being used for selectively driving the pixel electrodes, thereon. In such an active matrix substrate, a storage capacitor may be provided between a TFT and a pixel electrode in order to realize a high contrast or the like. These constituent elements are provided on the substrate so as to form a stacked structure. An interlayer insulating film is formed between the respective constituent elements so that electrical short-circuit or the like does not occur therebetween. In such an active matrix substrate, a gate insulating film constituting a TFT and an interlayer insulating film (or a capacitor insulating film constituting a storage capacitor) are typically formed by patterning a single insulating film formed over the entire surface of the substrate.

For example, JP-A-2007-243001 discloses a technique in which, in a TFT having a bottom-gate bottom-contact structure, a gate insulating film and an interlayer insulating film between a gate electrode and a source electrode are formed by patterning a single insulating film. Furthermore, for example, JP-A-2005-79598 discloses a technique in which a gate insulating film is locally formed on an upper portion of a gate electrode and the periphery thereof by depositing an insulating substance over the entire surface of a substrate by chemical vapor deposition (CVD) and patterning the deposited film.

A gate insulating film, a capacitor insulating film, and an interlayer insulating film, all of which are formed on an active matrix substrate, have different uses and functions, requirement specifications (e.g., the type of material and the film thickness) of these films are different from each other. However, as disclosed in JP-A-2007-243001, when a gate insulating film and an interlayer insulating film are formed by patterning a single insulating film formed over the entire surface of a substrate, the material and the film thickness of the gate insulating film and the interlayer insulating film are limited to one material and one thickness. Therefore, there may be a technical problem that it is difficult to individually meet specifications required for the respective gate insulating film and interlayer insulating film. According to the technique disclosed in JP-A-2005-79598, since a gate insulating film is formed by patterning a single insulating film formed over the entire surface of a substrate, there may be a technical problem that deflection of the substrate tends to be generated by a stress generated in the film during the process of forming the film. In addition, a part of the insulating film formed over the entire surface of the substrate is removed and wasted in the patterning process, resulting in a technical problem that such a waste is contrary to requirements of resource saving and a low cost.

### SUMMARY

An advantage of some aspects of the invention is to provide a substrate for a semiconductor device, for example, the substrate having transistors thereon and being capable of individually meeting respective specifications required for a plurality of insulating films, such as a gate insulating film and an interlayer insulating film, formed on the substrate, and capable of meeting the requirements of resource saving and a low cost, a method for producing the substrate, a semiconductor device including such a substrate for a semiconductor device, and an electronic apparatus including such a semiconductor device.

According to a first aspect of the invention, there is provided a substrate for a semiconductor device, the substrate including a substrate; a transistor disposed on the substrate and including a semiconductor layer, a first insulating film provided in the form of islands so as to at least partly overlap with the semiconductor layer in plan view on the substrate, and a gate electrode disposed so as to face the semiconductor layer with the first insulating film therebetween; and a second insulating film that is disposed on the substrate as substantially the same film as the first insulating film and that is formed in the form of islands so that at least one of the material and the thickness of the second insulating film is different from that of the first insulating film.

The substrate for a semiconductor device according to the first aspect of the invention is used as, for example, an active matrix substrate in a display device such as an electrophoretic display device driven by an active-matrix driving method, and includes, for example, a plurality of transistors on a substrate.

Each of the transistors includes a semiconductor layer, a first insulating film, and a gate electrode. The first insulating film is formed in the form of islands so as to at least partly overlap with the semiconductor layer in plan view on the substrate. The gate electrode is disposed so as to face the semiconductor layer with the first insulating film therebetween. That is, the first insulating film functions as a so-called gate insulating film that electrically insulates the semiconductor layer from the gate electrode. Herein, the phrase “formed in the form of islands” according to embodiments of the invention means that a film is locally formed in a specific region on a substrate by, for example, an application method, and excludes that a film is disposed over the entire surface of a substrate and that a film is formed over the entire surface of a substrate in a production process.

Note that the transistors may have a top-gate structure in which a gate electrode is disposed on the upper layer side of a semiconductor layer in a stacked structure provided on a substrate or a bottom-gate structure in which a gate electrode is disposed on the lower layer side of a semiconductor layer in a stacked structure provided on a substrate. Alternatively, the transistor may have a double-gate structure in which a gate electrode is disposed on each of the upper layer side and the lower electrode side of a semiconductor layer.

The second insulating film is disposed as substantially the same film as the first insulating film and formed in the form of islands so that at least one of the material and the thickness of the second insulating film is different from that of the first insulating film. The second insulating film is formed on the substrate as, for example, an interlayer insulating film that electrically insulates between two electrically conductive layers or a capacitor insulating film that constitutes a storage capacitor.

The material and the thickness of the first insulating film functioning as a gate insulating film affects the performance of the transistor, for example, the performance related to a switching operation. For example, in a transistor, a channel is formed in a channel region by an electric field generated by a gate voltage applied to the gate electrode, and the transistor turns to the on-state. The magnitude of this electric field varies depending on the thickness and the type of material of the first insulating film. In particular, in order to more reliably perform a switching operation of a transistor, it is believed that the electric field applied to the channel region is preferably large. Accordingly, the first insulating film is preferably formed so as to have a small thickness using a material having a large relative dielectric constant.

On the other hand, for example, when the second insulating film is provided between a pair of electrically conductive layers having a potential difference that temporally varies in order to electrically insulate between the electrically conductive layers, the second insulating film preferably has a large thickness so as to suppress cross-talk between the electrically conductive layers. That is, in order to reduce an electric field generated between the electrically conductive layers (i.e., in order to ensure a sufficiently large distance between the electrically conductive layers, the film thickness of the second insulating film is preferably large.

In the first aspect of the invention, the first insulating film and the second insulating film are formed respectively in the form of islands so that at least one of the material and the thickness of the second insulating film is different from that of the first insulating film. That is, the first insulating film and the second insulating film are selectively or locally formed by, for example, an application method in regions where the respective first insulating film and second insulating film should be formed so that at least one of the material and the thickness of the second insulating film is different from that of the first insulating film. Accordingly, even when the specifications (such as the material and the film thickness) respectively required for the first insulating film and the second insulating film are different from each other, it is possible to individually meet the respective specifications.

Incidentally, when the first insulating film and the second insulating film are formed on the same layer, unlike the first aspect of the invention, in general, these insulating films are formed by, for example, patterning a single film formed over the entire surface of a substrate. However, when the first insulating film and the second insulating film are formed in this manner, the materials and the film thicknesses of the two films cannot be individually determined. That is, since the first insulating film and the second insulating film are formed from a single film in a production process, the materials and the film thicknesses of the insulating films are limited to the same material and the same thickness. Therefore, it is difficult to determine the materials and the film thicknesses so as to meet specifications that are respectively required for the first insulating film and the second insulating film. Thus, according to the first aspect of the invention, the first insulating film and the second insulating film can be formed so that at least one of the material and the film thickness of the second insulating film is different from that of the first insulating film. Therefore, even when specifications required for the first insulating film and the second insulating film are different from each other, the specifications can be suitably met. That is, according to the first aspect of the invention, the material and the film thickness can be individually determined for the first insulating film and the second insulating film.

Furthermore, since the first insulating film and the second insulating film are each formed in the form of islands, materials are not wasted, as compared with the case where these insulating films are formed by patterning a single film. Specifically, since the insulating films are formed by an application method or the like in regions where the insulating films are to be formed, requirements for resource saving and a low cost can also be satisfied.

As described above, according to the substrate for a semiconductor device according to the first aspect of the invention, by individually meeting the specifications required to the respective first insulating film and the second insulating film, it is possible to meet the requirement of resource saving and a low cost while a high-performance transistor is provided on the substrate.

In accordance with an embodiment of the invention, the substrate for a semiconductor device may further include a pair of capacitor electrodes disposed so as to face each other with the second insulating film therebetween.

According to this embodiment, the second insulating film is formed as a part of a capacitor constituting an electric circuit together with a transistor on the substrate. Specifically, the capacitor is formed by sandwiching the second insulating film between a pair of capacitor electrodes, and the second insulating film functions as a so-called capacitor insulating film. For example, when the substrate for a semiconductor device is used as an active matrix substrate, the second insulating film may constitute a storage capacitor for improving a storage property of a transistor (i.e., a property for storing the electric potential of a pixel electrode that is electrically connected to the drain of a transistor).

The second insulating film functioning as a capacitor insulating film in this manner is formed so that at least one of the material and the thickness thereof is different from that of the first insulating film functioning as a gate insulating film. Accordingly, the first insulating film and the second insulating film can be formed so that the first insulating film meets the specification required for the gate insulating film and the second insulating film meets the specification required for the capacitor insulating film. For example, the material and the thickness of the second insulating film can be determined independently of those of the first insulating film functioning as a gate insulating film in order to change the capacitance of the capacitor.

In accordance with another embodiment of the invention, the substrate for a semiconductor device may further include a data line that is electrically connected to the semiconductor layer; and a gate line that intersects with the data line and that is electrically connected to the gate electrode, wherein the second insulating film is provided between the data line and the gate line.

According to this embodiment, the second insulating film is formed as an interlayer insulating film disposed between the data line and the gate line in order to prevent short-circuit between the data line and the gate line that intersect each other.

In general, the potentials of the data line (source line) and the gate line are different from each other. Therefore, since the potential difference (i.e., the electric field) between the data line and the gate line temporally varies, the potentials of the data line and the gate line are influenced each other to a varying degree (that is, cross-talk occurs, thereby disturbing the potentials of the lines). Such an interaction can be reduced by determining the thickness of the second insulating film to be large, the second insulating film being formed so as to be interposed between the data line and the gate line. Specifically, by determining the thickness of the second insulating film to be large, a large distance between the data line and the gate line can be ensured, and thus it is possible to suppress the magnitude of the electric field generated between the data line and the gate line. As a result, the interaction described above can be effectively reduced.

In this embodiment, even when the thickness of the second insulating film is determined to be large, it is not necessary to determine the thickness of the first insulating film to be large at the same time. That is, the thickness of the second insulating film can be increased in order to reduce the interaction between the data line and the gate line, and in addition, the thickness of the first insulating film can be determined to be small in order to ensure the performance of the transistor.

In accordance with the above-described embodiment in which a pair of capacitor electrodes are provided, the substrate for a semiconductor device may further include a data line that is electrically connected to the semiconductor layer; a third insulating film that is disposed as substantially the same film as the first insulating film and the second insulating film and that is formed in the form of islands so that at least one of the material and the thickness of the third insulating film is different from that of at least one of the first insulating film and the second insulating film; and a gate line that is disposed so as to face the data line with the third insulating film therebetween, that intersects with the data line, and that is electrically connected to the gate electrode.

In this case, the third insulating film can function as an interlayer insulating film that electrically insulates between the data line and the gate line that intersect each other.

In particular, the third insulating film is formed in the form of islands so that at least one of the material and the thickness of the third insulating film is different from that of at least one of the first insulating film and the second insulating film. Accordingly, the first, second, and third insulating films can be formed so that the first insulating film meets the specification required for the gate insulating film, the second insulating film meets the specification required for the capacitor insulating film, and the third insulating film can meets the specification required for the interlayer insulating film that electrically insulates the data line from the gate line.

Since the third insulating film is also formed in the form of islands similarly to the first insulating film and the second insulating film, materials are not wasted, as compared with the case where these insulating films are formed by patterning a single film. Specifically, since the third insulating film is also formed by an application method or the like in regions where the third insulating film is to be formed, requirements for resource saving and a low cost can also be met.

According to a second aspect of the invention, there is provided a method for producing a substrate for a semiconductor device, the substrate including a substrate and a transistor provided on the substrate and including a semiconductor layer, a first insulating film, and a gate electrode, the method including forming the semiconductor layer; forming the first insulating film in the form of islands so as to at least partly overlap with the semiconductor layer in plan view on the substrate; forming the gate electrode so as to face the semiconductor layer with the first insulating film therebetween; and forming a second insulating film as substantially the same film as the first insulating film in the form of islands so that at least one of the material and the thickness of the second insulating film is different from that of the first insulating film.

According to the second aspect of the invention, the above-described substrate for a semiconductor device of the first aspect of the invention (but including various embodiments thereof) can be produced. In particular, the method includes forming a first insulating film in the form of islands, and forming a second insulating film as substantially the same film as the first insulating film in the form of islands so that at least one of the material and the thickness of the second insulating film is different from that of the first insulating film. Accordingly, the first insulating film and the second insulating film can be formed so as to individually meet the specifications required for the respective insulating films, and thus the performance of the transistors can be effectively improved.

In accordance with an embodiment of the method for producing a substrate for a semiconductor device, the first insulating film may be formed by applying an insulating material on the substrate in a region where the first insulating film is to be formed, and the second insulating film may be formed by applying an insulating material on the substrate in a region where the second insulating film is to be formed.

According to this embodiment, the first insulating film and the second insulating film are formed using, for example, an ink jet method by applying an insulating material on the substrate in regions where the respective insulating films are to be formed. Thus, the first insulating film and the second insulating film can be easily formed so that at least one of the material and the thickness of the second insulating film is different from that of the first insulating film.

Furthermore, since the first insulating film and the second insulating film are formed not by patterning a single film but by applying a material, the material is not wasted in the process of forming the insulating films. That is, a substrate for a semiconductor device, the substrate including high-performance transistors, can be produced while meeting the requirements of resource saving and a low cost.

According to a third aspect of the invention, there is provided a semiconductor device including the substrate for a semiconductor device according to the first aspect of the invention (but including various embodiments thereof).

The semiconductor device according to the third aspect of the invention includes the above-described substrate for a semiconductor device according to the first aspect of the invention. Therefore, it is possible to provide various display devices such as electrophoretic display devices, liquid crystal display devices, and organic electroluminescence (EL) display devices that can realize a high-quality display, for example.

According to a fourth aspect of the invention, there is provided an electronic apparatus including the semiconductor device according to the third aspect of the invention (but including various embodiments thereof).

The electronic apparatus according to the fourth aspect of the invention includes the semiconductor device according to the third aspect of the invention. Therefore, for example, it is possible to realize electrophoretic display devices such as an electronic paper sheet, electrochromic devices, light-emitting diode (LED) devices, liquid crystal devices, electrowetting devices, and electron emission devices (such as a field-emission display and a conduction electron-emitter display) that can display high-quality images. Furthermore, as an electronic apparatus according to the fourth aspect of the invention, it is also possible to realize various electronic apparatuses such as projection display devices, televisions, mobile phones, electronic notebooks, word processors, view-finder type video tape recorders, direct-monitor-view type video tape recorders, work stations, videophones, POS terminals, touch panels, and sensors formed on a surface of the artificial skin.

The operation and other advantages of the invention will become apparent from embodiments described below.

### BRIEF DESCRIPTION OF THE DRAWINGS

The invention will be described with reference to the accompanying drawings, wherein like numbers reference like elements.

FIG. 1 is a block diagram showing the overall structure of an electrophoretic display panel according to a first embodiment.

FIG. 2 is an example of a circuit diagram of a pixel of the electrophoretic display panel according to the first embodiment.

FIG. 3 is another example of a circuit diagram of a pixel of the electrophoretic display panel according to the first embodiment.

FIG. 4 is an enlarged plan view of a display portion of the electrophoretic display panel according to the first embodiment.

FIG. 5 is a cross-sectional view taken along line V-V of FIG. 4.

FIG. 6 is an enlarged plan view of a display portion of an electrophoretic display panel according to a second embodiment.

FIG. 7 is a cross-sectional view taken along line VII-VII of FIG. 6.

FIG. 8 is an enlarged plan view of a display portion of an electrophoretic display panel according to a third embodiment.

FIG. 9 is a cross-sectional view taken along line IX-IX of FIG. 8.

FIG. 10 is an enlarged plan view of a display portion of an electrophoretic display panel according to a fourth embodiment.

FIG. 11 is an enlarged plan view of a display portion of an electrophoretic display panel according to a fifth embodiment.

FIG. 12 is an enlarged plan view of a display portion of an electrophoretic display panel according to a sixth embodiment.

FIG. 13 is an enlarged plan view of a display portion of an electrophoretic display panel according to a seventh embodiment.

FIG. 14 is a cross-sectional view taken along line XIV-XIV of FIG. 13.

FIG. 15 is an enlarged plan view of a display portion of an electrophoretic display panel according to an eighth embodiment.

FIG. 16 is a cross-sectional view taken along line XVI-XVI of FIG. 15.

FIG. 17 is an enlarged plan view of a display portion of an electrophoretic display panel according to a ninth embodiment.

FIGS. 18A to 18E are process cross-sectional views showing a method for producing an active matrix substrate according to the first embodiment.

FIG. 19 is a perspective view showing the structure of an electronic paper sheet which is an example of an electronic apparatus to which an electrophoretic display device is applied.

FIG. 20 is a perspective view showing the structure of an electronic notebook which is an example of an electronic apparatus to which an electrophoretic display device is applied.

### DESCRIPTION OF EXEMPLARY EMBODIMENTS

Embodiments of the invention will now be described with reference to the drawings. In the embodiments below, a description will be made of, as an example, an active-matrix driving electrophoretic display panel which is an example of a semiconductor device according to the invention, the electrophoretic display panel including an active matrix substrate which is an example of a substrate for a semiconductor device according to the invention.

### Electrophoretic Display Panel

### First Embodiment

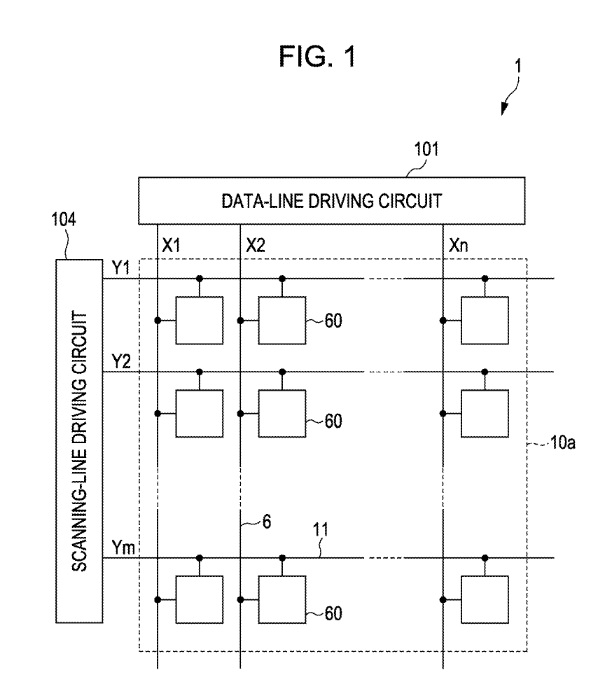

An electrophoretic display panel according to a first embodiment will now be described with reference to FIGS. 1 to 5.

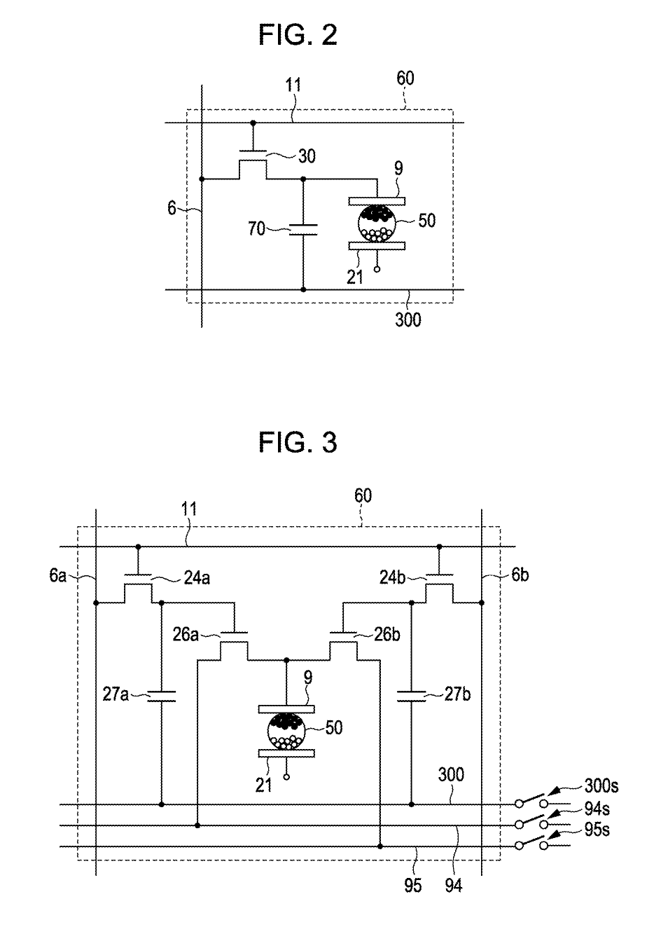

First, the overall structure of the electrophoretic display panel of this embodiment will now be described with reference to FIGS. 1 and 2.

FIG. 1 is a block diagram showing the overall structure of the electrophoretic display panel according to this embodiment.

In FIG. 1, an electrophoretic display panel 1 according to this embodiment includes a display portion 10a in which pixels 60 are arranged in a matrix (in a two-dimensional plane) of m rows and n columns. In the display portion 10a, m scanning lines 11 (i.e., scanning lines Y1, Y2, . . . , Ym) and n data lines 6 (i.e., data lines X1, X2, . . . , Xn) are provided so as to intersect each other. Specifically, the m scanning lines 11 extend in a row direction (i.e., X direction), and the n data lines 6 extend in a column direction (i.e., Y direction). The pixels 60 are arranged at positions corresponding to intersections of the m scanning lines 11 and the n data lines 6. Note that the scanning lines 11 are an example of “gate lines” according to the invention, and the data lines 6 are an example of “data lines” according to the invention.

The electrophoretic display panel 1 includes a scanning-line driving circuit 104 and a data-line driving circuit 101 for supplying scanning signals and image signals, respectively, that are necessary for driving these pixels 60.

The scanning-line driving circuit 104 sequentially supplies a scanning signal to each of the scanning lines Y1, Y2, . . . , Ym in a pulse-like manner. On the other hand, the data-line driving circuit 101 supplies image signals to the data lines X1, X2, . . . , Xn so as to synchronize with a supply timing of the scanning signals supplied from the scanning-line driving circuit 104. Each image signal has a binary level, namely, a high-potential level (hereinafter referred to as “high level”, for example, 5 V) or a low-potential level (hereinafter referred to as “low level”, for example, 0 V).

In this embodiment, the scanning-line driving circuit 104 and the data-line driving circuit 101 are installed in the electrophoretic display panel. Alternatively, these circuits 104 and 101 may be provided outside as external ICs bonded to a chip on film (COF) or the like.

FIG. 2 is a circuit diagram of one pixel 60 in the display portion 10a of the electrophoretic display panel 1 according to this embodiment.

In FIG. 2, the pixel 60 is configured so that an electrophoretic element 50 is sandwiched between a pixel electrode 9 and a counter electrode 21 that are respectively formed on surfaces of a pair of substrates (i.e., an element substrate and a counter substrate described below) disposed so as to face each other, thereby performing gradation display. The element substrate (but including a stacked structure formed on the element substrate) on which the pixel electrode 9 is formed constitutes an active matrix substrate which is an example of a “substrate for a semiconductor device” according to the invention.

The electrophoretic element 50 is composed of a plurality of microcapsules, each of which contains electrophoretic particles. Each of the microcapsules is configured so that, for example, a dispersion medium, a plurality of white particles, and a plurality of black particles are enclosed inside a coating. The coating functions as an outer shell of the microcapsule, and is composed of an optically transparent polymer such as an acrylic resin, e.g., polymethyl methacrylate or polyethyl methacrylate; urea resin; or gum arabic. The dispersion medium is a medium that disperses the white particles and the black particles in the microcapsule (that is, in the coating). Examples of the dispersion medium include water; alcohol solvents such as methanol, ethanol, isopropanol, butanol, octanol, and methyl cellosolve; various esters such as ethyl acetate, and butyl acetate; ketones, such as acetone, methyl ethyl ketone, and methyl isobutyl ketone; aliphatic hydrocarbons such as pentane, hexane, and octane; alicyclic hydrocarbons such as cyclohexane and methylcyclohexane; aromatic hydrocarbons such as benzene, toluene, xylene, and benzenes having a long-chain alkyl group, e.g., hexylbenzene, heptylbenzene, octylbenzene, nonylbenzene, decylbenzene, undecylbenzene, dodecylbenzene, tridecylbenzene, and tetradecylbenzene; halogenated hydrocarbons such as methylene chloride, chloroform, carbon tetrachloride, and 1,2-dichloroethane; carboxylates; and other various types of oil. These dispersion media may be used alone or in combination. The dispersion medium may be mixed with a surfactant. The white particles are, for example, particles (polymer particles or colloids) composed of a white pigment such as titanium dioxide, zinc white (zinc oxide), or antimony trioxide, and are, for example, negatively charged. The black particles are, for example, particles (polymer particles or colloids) composed of a black pigment such as aniline black or carbon black, and are, for example, positively charged. Therefore, the white particles and the black particles can move in the dispersion medium owing to an electric field that is generated by a potential difference between the pixel electrode 9 and the counter electrode 21.

These pigments may optionally contain additives such as an electrolyte; a surfactant; metallic soap; a resin; rubber; oil; varnish; a charge control agent formed of particles of a compound or the like; a dispersing agent such as a titanium coupling agent, an aluminum coupling agent, or a silane coupling agent; a lubricant; and a stabilizing agent.

Each of the pixels 60 includes a TFT 30 for pixel switching and a storage capacitor 70. The TFT 30 is an example of a “transistor” according to the invention.

The gate of the TFT 30 is electrically connected to the scanning line 11, the source thereof is electrically connected to the data line 6, and the drain thereof is connected to the pixel electrode 9. The TFT 30 outputs the image signal, which is supplied from the data-line driving circuit 101 (refer to FIG. 1) through the data line 6, to the pixel electrode 9 at the timing corresponding to the scanning signal, which is supplied in a pulse-like manner from the scanning-line driving circuit 104 (refer to FIG. 1) through the scanning line 11.

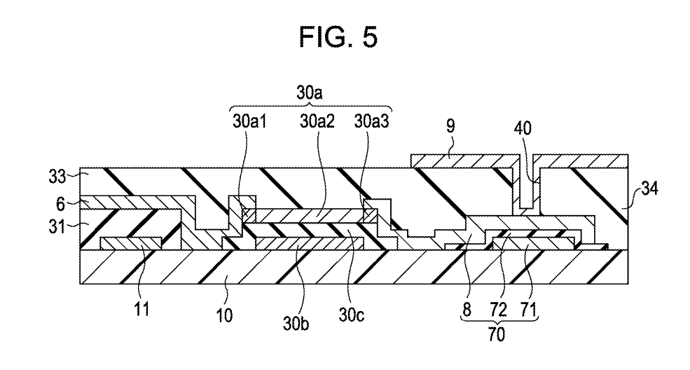

The storage capacitor 70 is constituted by sandwiching a capacitor insulating film, which is an example of a “third insulating film” according to the invention, between a pair of electrodes (specifically, a capacitor electrode 71 and a relay layer 8 which will be described below with reference to FIG. 5). Here, one of the pair of electrodes (specifically, the relay layer 8 described below) is electrically connected to the drain of the TFT 30 and the pixel electrode 9, and the other electrode (specifically the capacitor electrode 71 described below) is electrically connected to a common potential line 300 that is held at a certain potential. The potential of the common potential line 300 may be a constant value or vary at a constant or inconstant period. By providing the storage capacitor 70 parallel to the pixel 60 in this manner, a storage property of the pixel electrode 9 to the image signal can be improved. When the storage property of a pixel can be satisfactorily ensured without providing the storage capacitor 70, the storage capacitor 70 may not be provided.

FIG. 3 shows another example of a circuit diagram of one pixel 60 in the display portion 10a of the electrophoretic display panel 1 according to this embodiment. In FIG. 3, portions common to those in FIG. 2 are assigned the same reference numerals, and a description of these portions is omitted as appropriate.

In FIG. 3, a pixel 60 includes a pixel electrode 9, a counter electrode 21 disposed so as to face the pixel electrode 9, and an electrophoretic element 50 provided between the pixel electrode 9 and the counter electrode 21, a first selection TFT 24a, a second selection TFT 24b, a first capacitor 27a, a second capacitor 27b, a first control TFT 26a, and a second control TFT 26b. Here, the first selection TFT 24a, the second selection TFT 24b, the first capacitor 27a, the second capacitor 27b, the first control TFT 26a, and the second control TFT 26b are each an example of a “transistor” according to the invention.

In the example shown in FIG. 3, unlike the above-described example shown in FIGS. 1 and 2, total 2n data lines 6 are provided so that two data lines 6 are electrically connected to each pixel 60. The 2n data lines 6 include n first data lines 6a arranged near one side (near the left side in the figure) of the pixel 60 and n second data lines 6b arranged near the other side (near the right side in the figure) of the pixel 60.

The first selection TFT 24a is formed as an N-channel TFT by using an amorphous semiconductor. The gate of the first selection TFT 24a is electrically connected to a scanning line 11, the source thereof is electrically connected to a first data line 6a, and the drain thereof is electrically connected to the first capacitor 27a. The first selection TFT 24a inputs an image signal, which is supplied from a data-line driving circuit through the first data line 6a, to the first capacitor 27a at a timing corresponding to a scanning signal that is supplied from a scanning-line driving circuit through the scanning line 11 in a pulse-like manner. Accordingly, the image signal is written into the first capacitor 27a.

The first capacitor 27a is a capacitive element for storing an image signal. One capacitor electrode of the first capacitor 27a is electrically connected to the drain of the first selection TFT 24a and the gate of the first control TFT 26a. The other capacitor electrode of the first capacitor 27a is electrically connected to a common potential line 300.

The first control TFT 26a is formed as an N-channel TFT by using an amorphous semiconductor. The gate of the first control TFT 26a is electrically connected to the first capacitor 27a and the drain of the first selection TFT 24a, the source thereof is electrically connected to a first control line 94, and the drain thereof is electrically connected to the pixel electrode 9. The first control TFT 26a outputs a first control potential S1, which is supplied from a power supply circuit through the first control line 94, to the pixel electrode 9 in accordance with the potential of the image signal that is stored in the first capacitor 27a. For example, when the image signal stored in the first capacitor 27a has the high level, the first control TFT 26a is in the on-state, and the first control potential S1 is supplied from the first control line 94 to the pixel electrode 9 through the first control TFT 26a that is in the on-state. On the other hand, when the image signal stored in the first capacitor 27a has the low level, the first control TFT 26a is in the off-state, and the first control line 94 and the pixel electrode 9 are electrically disconnected from each other by the first control TFT 26a that is in the off-state.

The second selection TFT 24b is formed as an N-channel TFT by using an amorphous semiconductor. The gate of the second selection TFT 24b is electrically connected to the scanning line 11, the source thereof is electrically connected to the second data line 6b, and the drain thereof is electrically connected to the second capacitor 27b. The second selection TFT 24b inputs an inverted image signal, which is supplied from the data-line driving circuit through the second data line 6b, to the second capacitor 27b at a timing corresponding to a scanning signal that is supplied from the scanning-line driving circuit through the scanning line 11 in a pulse-like manner. Accordingly, the inverted image signal is written into the second capacitor 27b.

The second capacitor 27b is a capacitive element for storing an inverted image signal. One capacitor electrode of the second capacitor 27b is electrically connected to the drain of the second selection TFT 24b and the gate of the second control TFT 26b. The other capacitor electrode of the second capacitor 27b is electrically connected to the common potential line 300 similarly to the other capacitor electrode of the first capacitor 27a.

The second control TFT 26b is formed as an N-channel TFT by using an amorphous semiconductor. The gate of the second control TFT 26b is electrically connected to the second capacitor 27b and the drain of the second selection TFT 24b, the source thereof is electrically connected to a second control line 95, and the drain thereof is electrically connected to the pixel electrode 9. The second control TFT 26b outputs a second control potential S2, which is supplied from the power supply circuit through the second control line 95, to the pixel electrode 9 in accordance with the potential of the inverted image signal that is stored in the second capacitor 27b. For example, when the inverted image signal stored in the second capacitor 27b has the high level, the second control TFT 26b is in the on-state, and the second control potential S2 is supplied from the second control line 95 to the pixel electrode 9 through the second control TFT 26b that is in the on-state. On the other hand, when the inverted image signal stored in the second capacitor 27b has the low level, the second control TFT 26b is in the off-state, and the second control line 95 and the pixel electrode 9 are electrically disconnected from each other by the second control TFT 26b that is in the off-state.

The first control line 94 and the second control line 95 are configured so that the first control potential S1 and the second control potential S2 can be respectively supplied from the power supply circuit thereto. The first control line 94 is electrically connected to the power supply circuit (not shown) through a switch 94s, and the second control line 95 is electrically connected to the power supply circuit through a switch 95s. The switches 94s and 95s are configured to be switched between the on-state and the off-state by a controller. When the switch 94s turns to the on-state, the first control line 94 and the power supply circuit are electrically connected to each other. When the switch 94s turns to the off-state, the first control line 94 becomes a high-impedance state in which the first control line 94 is electrically disconnected. When the switch 95s turns to the on-state, the second control line 95 and the power supply circuit are electrically connected to each other. When the switch 95s turns to the off-state, the second control line 95 becomes a high-impedance state in which the second control line 95 is electrically disconnected.

The state of the first control TFT 26a is switched between the on-state and the off-state in accordance with the image signal that is stored in the first capacitor 27a, and the state of the second control TFT 26b is switched between the on-state and the off-state in accordance with the inverted image signal (i.e., a signal acquired by inverting the binary level of the image signal) that is stored in the second capacitor 27b. Accordingly, the on- or off-state of the first control TFT 26a and that of the second control TFT 26b are different from each other. More specifically, when the first control TFT 26a is in the on-state, the second control TFT 26b is in the off-state. On the other hand, when the first control TFT 26a is in the off-state, the second control TFT 26b is in the on-state. Accordingly, each pixel electrode 9 of the plurality of pixels 60 is electrically connected to either the first control line 94 or the second control line 95 in accordance with the image signal stored in the first capacitor 27a and the inverted image signal stored in the second capacitor 27b. At this moment, each pixel electrode 9 of the plurality of pixels 60 is supplied with the first control potential S1 or the second control potential S2 from the power supply circuit or becomes the high-impedance state in accordance with the on- and off-states of the switches 94s and 95s.

More specifically, in a pixel 60 to which an image signal at the high level is supplied (in other words, an inverted image signal at the low level is supplied), of the first control TFT 26a and the second control TFT 26b, only the first control TFT 26a is in the on-state, and the pixel electrode 9 of the pixel 60 is electrically connected to the first control line 94 and is supplied with the first control potential S1 from the power supply circuit or becomes the high-impedance state in accordance with the on- or off-state of the switch 94s. On the other hand, in a pixel 60 to which an image signal at the low level is supplied (in other words, an inverted image signal at the high level is supplied), of the first control TFT 26a and the second control TFT 26b, only the second control TFT 26b is in the on-state, and the pixel electrode 9 of the pixel 60 is electrically connected to the second control line 95 and is supplied with the second control potential S2 from the power supply circuit or becomes the high-impedance state in accordance with the on- or off-state of the switch 95s.

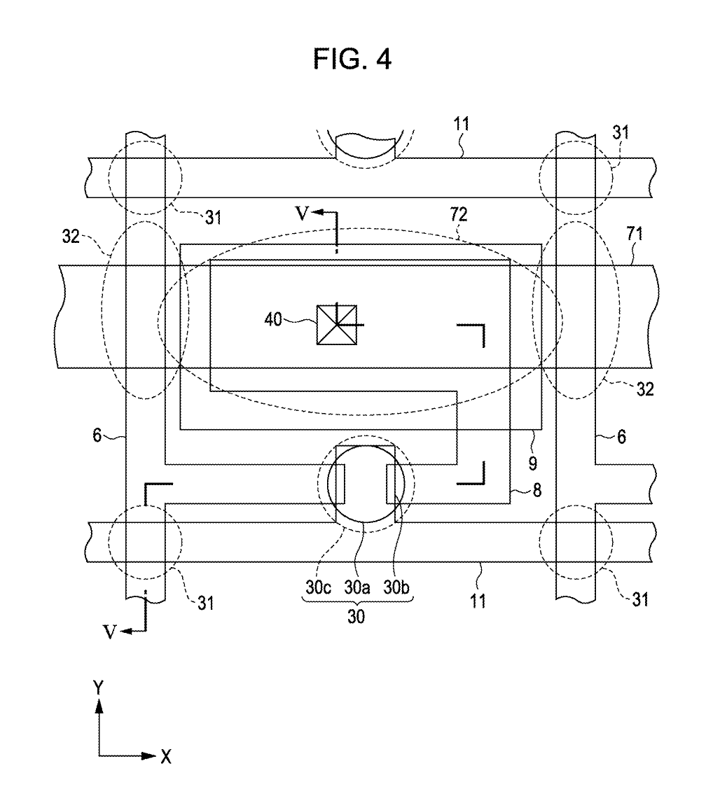

Next, a specific structure of the display portion 10a of the electrophoretic display panel 1 according to this embodiment will be described with reference to FIGS. 4 and 5.

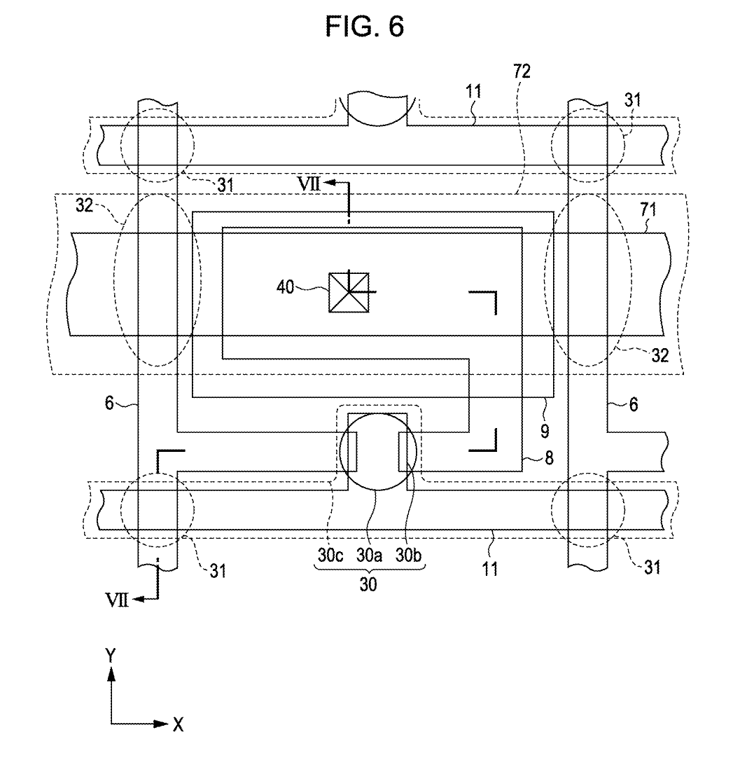

FIG. 4 is an enlarged plan view of the display portion 10a of the electrophoretic display panel 1 according to this embodiment. FIG. 5 is a cross-sectional view taken along line V-V of FIG. 4. In FIGS. 4 and 5, a reduction scale of respective layers and elements is appropriately changed to enlarge the respective layers and elements to a recognizable size in the figures. This also applies to FIGS. 6 to 18 described below.

In FIG. 5, an element substrate 10 is an example of a “substrate” according to the invention and is a substrate formed using polyethylene terephthalate (PET) as a material. Alternatively, for example, polyethersulfone (PES), polyetherimide, polyetherketone, polyphenylene sulfide, polyarylate, polyimide, polycarbonate (PC), aromatic polyester (liquid crystal polymer), cellulose triacetate (TAC), cellulose acetate propionate (CAP), or the like may also be used as the material of the element substrate 10. The use of such an organic insulating substrate as the element substrate 10 can contribute to a reduction in the weight and an improvement in the flexibility of the electrophoretic display panel. Alternatively, an inorganic insulating substrate such as a glass substrate, a silicon substrate, or a thin metal sheet may also be used as the material of the element substrate 10.

Although not shown in the figure in this embodiment, an underlying film may be formed on a surface of the element substrate 10. For example, an organic insulating material such as polyimide, or an inorganic material such as a silicon nitride film may be used as the material of the underlying film. By forming the underlying film, irregularities that are present on the surface of the element substrate 10 can be planarized, and degassing from the element substrate 10 and a gas, moisture, and the like that intrude from the outside and pass through the element substrate 10 can be effectively blocked. Accordingly, a stacked structure having a good quality can be formed on the upper layer side.

Scanning lines 11 and data lines 6 are provided on the element substrate 10. For example, the scanning lines 11 may be composed of aluminum (Al) and have a thickness of 100 nm. For example, the data lines 6 may be composed of gold (Au) and have a thickness of 100 nm.

As shown in FIG. 4, in plan view on the element substrate 10, the scanning lines 11 and the data lines 6 are arranged so as to extend in the X direction and the Y direction, respectively. Examples of the materials of the scanning lines 11 and the data lines 6 include electrically conductive materials such as metals, e.g., aluminum (Al), tungsten (W), titanium (Ti), titanium nitride (TiN), copper, and gold; and organic electrically conductive materials such as carbon nanotube, graphene, and polyethylenedioxythiophene (PEDOT). The film thickness is not limited to 100 nm.

As shown in FIG. 5, a data line 6 is provided on the upper layer side of a scanning line 11 with an interlayer insulating film 31 therebetween. Note that the interlayer insulating film 31 is an example of a “second insulating film” according to the invention.

The interlayer insulating film 31 is formed in the form of islands on the element substrate 10 in regions where the data lines 6 and the scanning lines 11 intersect each other by applying an insulating material by an application method such as an ink jet method.

Examples of the material of the interlayer insulating film 31 than can be used include organic insulating materials such as polyvinyl acetate, polymethyl methacrylate, polystyrene, polyimides, polyamides, polyesters, polyacrylates, photo-radical polymerizable photo curable resins, photo-cationic polymerizable photo curable resins, polyvinylphenol, polyvinyl alcohol, novolak resins, cyanoethyl pullulan, fluorine-containing polymers, polyolefin polymers typified by polyisobutylene, polyvinylphenol octadecyltrichlorosilane (PVP-OTS), copolymers thereof, and photosensitive resins; and inorganic materials such as silicon oxide and silicon nitride.

A scanning signal and an image signal having potentials different from each other are supplied to each data line 6 and each scanning line 11, respectively, and thus an electric field that temporally varies on the basis of the potential difference is generated between the data line 6 and the scanning line 11. The magnitude of this electric field is preferably small because the electric field generated in such a manner causes cross-talk between the data line 6 and the scanning line 11. For this reason, in this embodiment, the thickness of the interlayer insulating film 31 is determined to be large, and a material having a small relative dielectric constant is used as the material of the interlayer insulating film 31. More specifically, the thickness of the interlayer insulating film 31 is determined to be in the range of about 20 nm to 100 μm, and a photosensitive acrylic resin having a relative dielectric constant of about 3.3 is used as the material of the interlayer insulating film 31. The thickness of the interlayer insulating film 31 is, for example, 1 μm.

When the data lines 6 and the scanning lines 11 are formed by an application method such as an inkjet method, wiring widths of the data lines 6 and the scanning lines 11 formed tend to be increased (typically increased by 20 to 30 μm or more), as compared with the case where these lines 6 and 11 are formed by, using a photolithographic method or the like, patterning a film formed in a solid manner. If the lines having such a large wiring width are formed, the capacitance generated between a data line 6 and a scanning line 11 increases, and thus the electric power consumption of the electrophoretic display panel 1 may be significantly increased. In this respect, in this embodiment, even in such a case, the magnitude of the electric field generated between the data line 6 and the scanning line 11 can be suppressed to be small by forming the interlayer insulating film 31 so as to have a large thickness, whereby the electric power consumption of the electrophoretic display panel 1 can be improved.

TFTs 30 are provided on the element substrate 10. In plan view on the element substrate 10, the TFTs 30 are arranged for respective pixels at positions corresponding to intersections of the scanning lines 11 arranged so as to extend in the X direction and the data lines 6 arranged so as to extend in the Y direction. Each of the TFTs 30 is composed of a semiconductor layer 30a, a gate electrode 30b, and a gate insulating film 30c.

The semiconductor layer 30a includes a source region 30a1, a channel region 30a2, and a drain region 30a3. The gate electrode 30b is provided so as to face the channel region 30a2 of the semiconductor layer 30a, with the gate insulating film 30c therebetween. In the semiconductor layer 30a, a lightly doped drain (LDD) region may be formed between the source region 30a1 and the channel region 30a2 or between the channel region 30a2 and the drain region 30a3. Note that the gate insulating film 30c is an example of a “first insulating film” according to the invention.

Here, as shown in FIG. 4, the gate electrode 30b is formed as a part of a scanning line 11 formed on the element substrate 10. In this embodiment, in a scanning line 11, which is mainly formed in the X direction, a portion of the scanning line 11, the portion being formed so as to partly protrude in the Y direction in a region that overlaps with the semiconductor layer 30a in plan view on the element substrate 10, functions as the gate electrode 30b.

The film thickness of the scanning lines 11 is preferably about 5 nm to 50 μm.

The material of the gate insulating film 30c is a polyamide resin and the gate insulating film 30c has a thickness of 200 nm. Examples of other materials that can be used as the gate insulating film 30c include organic insulating materials such as polyvinyl acetate, polymethyl methacrylate, polystyrene, polyimides, polyesters, polyacrylates, photo-radical polymerizable photo curable resins, photo-cationic polymerizable photo curable resins, polyvinylphenol, polyvinyl alcohol, novolak resins, cyanoethyl pullulan, fluorine-containing polymers, polyolefin polymers typified by polyisobutylene, PVP-OTS, copolymers thereof, and photosensitive resins; and inorganic materials such as silicon oxide and silicon nitride.

From the standpoint of improving the performance of the TFTs 30, it is preferable that the gate insulating film 30c have a small film thickness and be composed of a material having a large relative dielectric constant. To meet this requirement, the film thickness of the gate insulating film 30c according to this embodiment is determined to be a small value in the range of about 10 nm to 1 μm. The film thickness of the gate insulating film 30c is preferably as small as possible, but is preferably determined to be small within a range in which electrical insulation between the semiconductor layer 30a and the gate electrode 30b can be reliably ensured. By determining the thickness of the gate insulating film 30c in this manner, both an improvement in the performance of the TFTs 30 and high reliability thereof can be achieved.

The semiconductor layer 30a is composed of pentacene. Examples of other materials that can be used as the semiconductor layer 30a include low-molecular weight organic semiconductor materials such as naphthalene, anthracene, tetracene, hexacene, phthalocyanine, perylene, hydrazone, triphenylmethane, diphenylmethane, stilbene, aryl vinyl, pyrazoline, triphenylamine, triarylamine, oligothiophene, and derivatives thereof; and high-molecular weight organic semiconductor materials such as poly-N-vinylcarbazole, polyvinylpyrene, polyvinylanthracene, polythiophene, polyhexylthiophene, poly(p-phenylenevinylene), polythienylenevinylene, polyarylamine, pyrene-formaldehyde resins, ethylcarbazole-formaldehyde resins, fluorene-bithiophene copolymers, fluorene-arylamine copolymers, and derivatives thereof. These organic semiconductor materials may be used alone or in combination of two or more. Alternatively, an oxide semiconductor such as IGZO, ZnO, TiO₂, or AlZnSnO, or silicon may be used as the material of the semiconductor layer 30a. The thickness of the semiconductor layer 30a is, for example, 50 nm. However, the thickness of the semiconductor layer 30a is not limited thereto and may be in the range of about 5 nm to 1 μm.

It is known that when an organic semiconductor material such as pentacene is used as a semiconductor layer, in general, the source region 30a1 and the drain region 30a3 are naturally formed in the semiconductor layer 30a that contacts the data line 6 and the relay layer 8, respectively. Introduction of an impurity or the like need not be performed. It is believed that this is because when the Fermi levels of a carrier of a semiconductor material and a carrier of a metal substantially coincide with each other, electric charges naturally flow.

The source region 30a1 is electrically connected to a data line 6 and configured so that an image signal supplied from the data line 6 is applied thereto.

The drain region 30a3 is electrically connected to the relay layer 8. The relay layer 8 is electrically connected to the pixel electrode 9 through a contact hole 40. Thus, an image signal supplied to the source region 30a1 is output from the drain region 30a3 at a timing at which a scanning signal is supplied to the gate electrode 30b (that is, at a timing at which the TFT 30 is driven to the on-state), whereby the image signal is applied to the pixel electrode 9 through the relay layer 8.

The relay layer 8 and a capacitor electrode 71 that is formed on the surface of the element substrate 10 sandwich a capacitor insulating film 72 to form a storage capacitor 70. The capacitor electrode 71 is electrically connected to the common potential line 300 (refer to FIG. 2), and thus is maintained at a certain potential.

The capacitor insulating film 72 is formed in the form of islands so as to partly cover the capacitor electrode 71 by applying an insulating material by an application method such as an ink jet method.

As described above, in order to improve the storage property of the TFT 30, the storage capacitor 70 is preferably formed so as to have a large capacitance. In this embodiment, in particular, a polyimide resin having a relative dielectric constant of about 3.6 is used as the material of the capacitor insulating film 72, and the capacitor insulating film 72 is formed so as to have a small thickness. The specific film thickness of the capacitor insulating film 72 is about 0.3 μm.

Considering that the potential difference applied to the gate insulating film 30c is 40 V or more whereas the potential difference applied to the capacitor insulating film 72 is about ±15 V, the thickness of the capacitor insulating film 72 is determined to be smaller than the thickness of the gate insulating film 30c.

The same material as that of the interlayer insulating film 31 or the gate insulating film 30c may be used as the material of the capacitor insulating film 72. The thickness of the capacitor insulating film 72 is not limited to 0.3 μm, and a thickness in the range of 10 nm to 1 μm may also be used.

In FIG. 4, in plan view on the element substrate 10, an interlayer insulating film 32 for electrically insulating the data lines 6 from the capacitor electrode 71 is formed in regions where the data lines 6 overlap with the capacitor electrode 71. The interlayer insulating film 32 is disposed as substantially the same film as the interlayer insulating film 31 described above. The interlayer insulating film 32 is also formed in the form of islands by applying an insulating material by an application method such as an ink jet method similarly to the interlayer insulating film 31, the capacitor insulating film 72, and the gate insulating film 30c.

Interlayer insulating films 33 and 34 are composed of a photosensitive acrylic resin and have a thickness of 1 μm. The same material as that of the interlayer insulating film 31 or the gate insulating film 30c may be used as the material of the interlayer insulating films 33 and 34. The thickness may also be in the range of 100 nm to 100 μm.

The pixel electrode 9 is composed of indium tin oxide (ITO) and has a thickness of 50 nm. Not only such a transparent electrode but also an opaque electrode composed of a metal or the like may also be used. The thickness may be also in the range of 5 nm to 1 μm.

As described above, the electrophoretic display panel 1 according to this embodiment is configured so that the materials and the thicknesses of the interlayer insulating film 31, the capacitor insulating film 72, and the gate insulating film 30c are different from each other among the three insulating films. Thus, the electrophoretic display panel 1 can individually meet specifications required for respective insulating films. As a result, an electrophoretic display panel that can display high-quality images can be realized.

### Second Embodiment

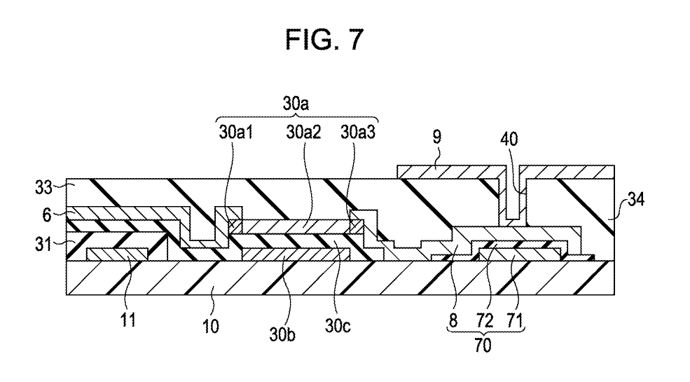

Next, the structure of an electrophoretic display panel according to a second embodiment will be described with reference to FIGS. 6 and 7. The overall structure of the electrophoretic display panel of the second embodiment is basically similar to that of the above-described electrophoretic display panel of the first embodiment. Therefore, a description of points common to the first embodiment is omitted as appropriate, and points different from the first embodiment will be mainly described.

FIG. 6 is an enlarged plan view of a display portion 10a of an electrophoretic display panel 1 according to the second embodiment. FIG. 7 is a cross-sectional view taken along line VII-VII of FIG. 6.

Referring to FIGS. 6 and 7, the second embodiment differs from the first embodiment in that, in plan view on an element substrate 10, a gate insulating film 30c is formed over a wider region than a scanning line 11 (that is, also including a gate electrode 30b). By widely forming the gate insulating film 30c in this manner, it is possible to effectively prevent the occurrence of a short-circuit defect between a semiconductor layer 30a and the gate electrode 30b due to, for example, the presence of a foreign substance between the gate electrode 30b and the semiconductor layer 30a, the data line 6, or the like in a process of producing the TFT 30, thus improving the quality of the TFT 30.

Furthermore, a capacitor insulating film 72 is also formed over a wider region than a capacitor electrode 71 in plan view on the element substrate 10. By widely forming the capacitor insulating film 72 in this manner, it is possible to effectively prevent the occurrence of a short-circuit defect between the capacitor electrode 71 and a relay layer 8 due to, for example, the presence of a foreign substance between the capacitor electrode 71 and the relay layer 8, which are a pair of electrodes constituting a storage capacitor 70, in a process of producing the storage capacitor 70, thereby improving the quality of the storage capacitor 70.

In plan view on the element substrate 10, in regions where an interlayer insulating film 31 is formed, the gate insulating film 30c is formed on the upper layer side of the interlayer insulating film 31 so as to overlap with the interlayer insulating film 31. Therefore, since a large interlayer distance between the data line 6 and the scanning line 11 can be ensured as compared with the first embodiment (that is, since the film thickness of the interlayer insulating film 31 in the first embodiment can be substantially increased), a mutual influence of signals between the data line 6 and the scanning line 11 can be effectively suppressed. As a result, the electrophoretic display panel 1 in which disturbance of image signals is small and which can display high-quality images can be realized.

### Third Embodiment

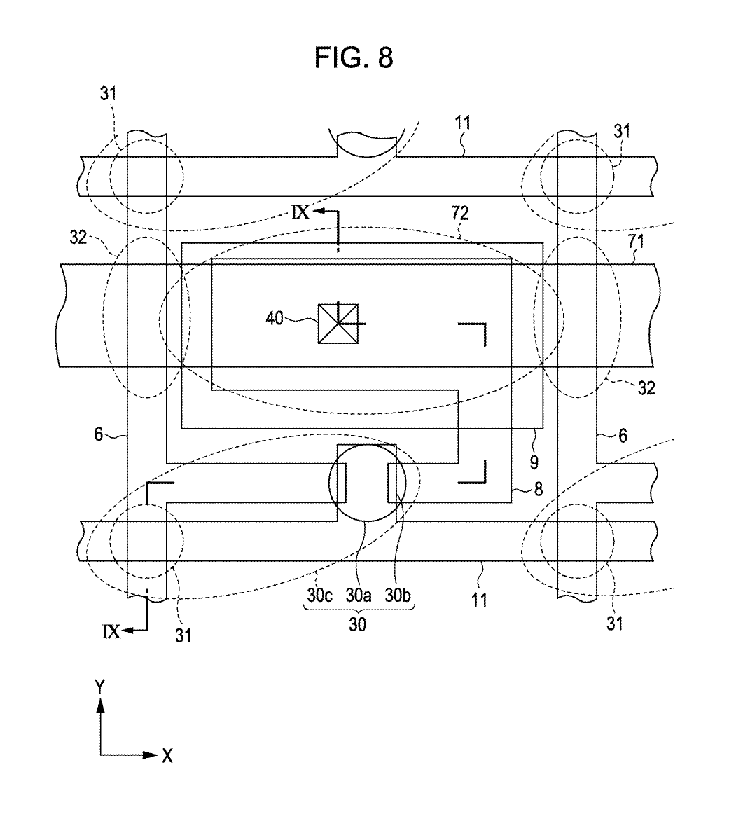

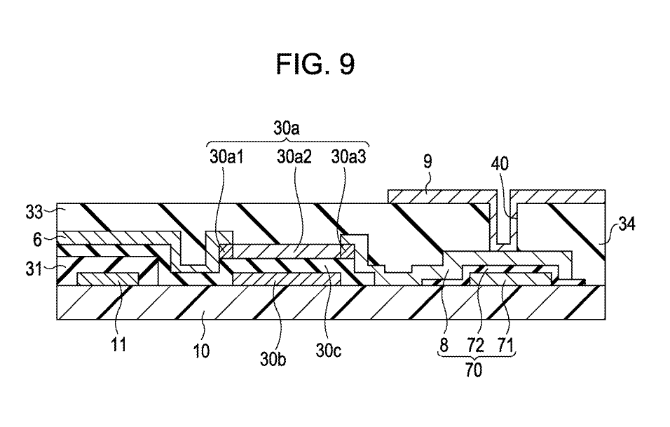

Next, the structure of an electrophoretic display panel according to a third embodiment will be described with reference to FIGS. 8 and 9. The overall structure of the electrophoretic display panel of the third embodiment is basically similar to that of the above-described electrophoretic display panel of the first embodiment. Therefore, a description of points common to the first embodiment is omitted as appropriate, and a point different from the first embodiment will be mainly described.

FIG. 8 is an enlarged plan view of a display portion 10a of an electrophoretic display panel 1 according to the third embodiment. FIG. 9 is a cross-sectional view taken along line IX-IX of FIG. 8.

Referring to FIGS. 8 and 9, in plan view on an element substrate 10, in regions where an interlayer insulating film 31 is formed, a gate insulating film 30c is formed on the upper layer side of the interlayer insulating film 31 so as to overlap with the interlayer insulating film 31. Therefore, since a large interlayer distance between a data line 6 and a scanning line 11 can be ensured as compared with the first embodiment (that is, since this is equivalent to that the thickness of the interlayer insulating film 31 is substantially increased), a mutual influence of signals between the data line 6 and the scanning line 11 can be effectively suppressed. As a result, the electrophoretic display panel 1 in which disturbance of image signals is small and which can display high-quality images can be realized.

In the third embodiment, unlike the second embodiment described above, it is not necessary to widely form the gate insulating film 30c over the scanning lines 11. Therefore, the amount of material necessary for forming the gate insulating film 30c can be suppressed to be small. Thus, an electrophoretic display panel that meets the requirements of resource saving and a low cost can be realized.

### Fourth Embodiment

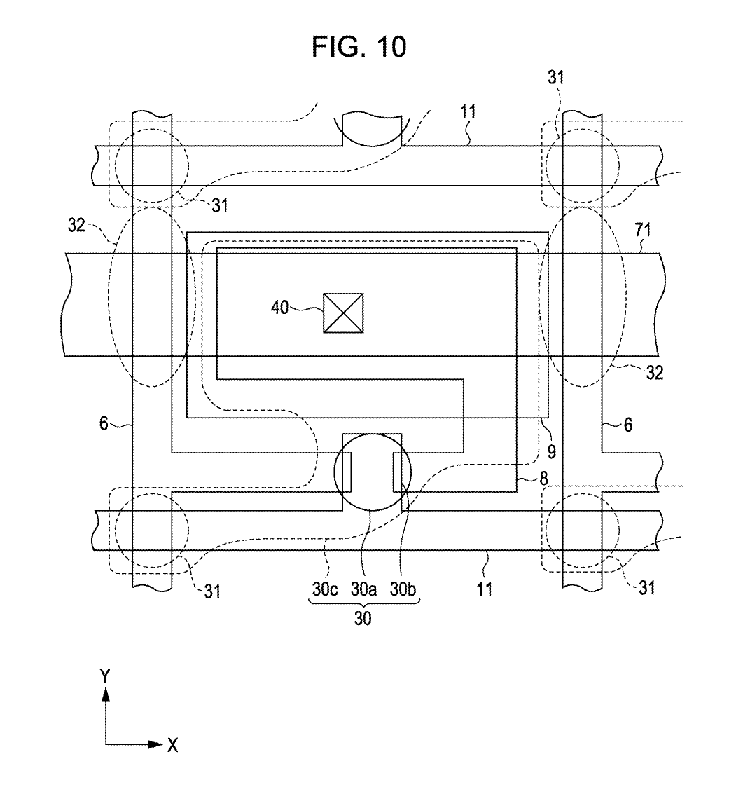

Next, the structure of an electrophoretic display panel according to a fourth embodiment will be described with reference to FIG. 10. The overall structure of the electrophoretic display panel of the fourth embodiment is basically similar to that of the electrophoretic display panel of the embodiments described above. Therefore, a description of points common to the above embodiments is omitted as appropriate, and points different from the above embodiments will be mainly described.

FIG. 10 is an enlarged plan view of a display portion 10a of an electrophoretic display panel 1 according to the fourth embodiment.

Referring to FIG. 10, in the fourth embodiment, a gate insulating film 30c and a capacitor insulating film 72 are integrally formed. That is, the gate insulating film 30c and the capacitor insulating film 72 can be formed in one step. Accordingly, the electrophoretic display panel 1 can be produced in a small number of steps, as compared with the first embodiment in which the gate insulating film 30c and the capacitor insulating film 72 are formed in separate steps. Thus, this structure can contribute to a reduction in the production cost.

In addition, in plan view on an element substrate 10, the gate insulating film 30c is formed so as to extend to a region where an interlayer insulating film 31 is formed. That is, in plan view on the element substrate 10, in regions where the interlayer insulating film 31 is formed, the gate insulating film 30c is formed on the upper layer side of the interlayer insulating film 31 so as to overlap with the interlayer insulating film 31. Accordingly, since a large interlayer distance between a data line 6 and a scanning line 11 can be ensured as compared with the first embodiment (that is, since the thickness of the interlayer insulating film 31 in the first embodiment can be substantially increased), a mutual influence of signals between the data line 6 and the scanning line 11 can be effectively suppressed. As a result, the electrophoretic display panel 1 in which disturbance of image signals is small and which can display high-quality images can be realized.

### Fifth Embodiment

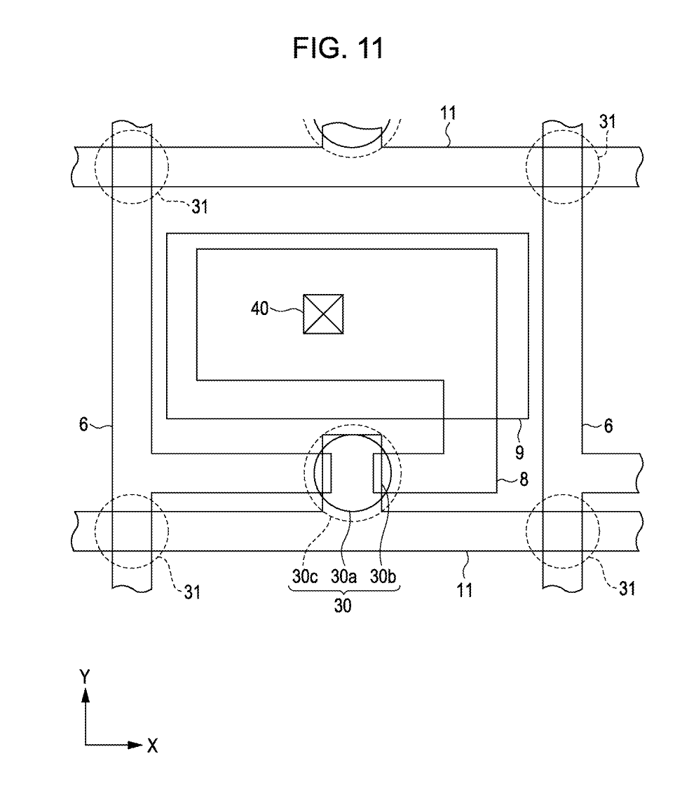

Next, the structure of an electrophoretic display panel according to a fifth embodiment will be described with reference to FIG. 11. The overall structure of the electrophoretic display panel of the fifth embodiment is basically similar to that of the electrophoretic display panel of the embodiments described above. Therefore, a description of points common to the above embodiments is omitted as appropriate, and a point different from the above embodiments will be mainly described.

FIG. 11 is an enlarged plan view of a display portion 10a of an electrophoretic display panel 1 according to the fifth embodiment.

Referring to FIG. 11, unlike the first embodiment described above, the storage capacitor 70 is not formed on an element substrate 10 in the fifth embodiment. That is, this embodiment corresponds to a case where a storage property of a TFT 30 can be sufficiently ensured even when the storage capacitor 70 is not provided. Since the storage capacitor 70 is not formed in this manner, the stacked structure on the element substrate 10 can be simplified accordingly. As a result, this structure can contribute to a suppression of the production cost due to a reduction in the number of production steps of the electrophoretic display panel and to realization of high definition due to the simplified stacked structure on the element substrate 10.

### Sixth Embodiment

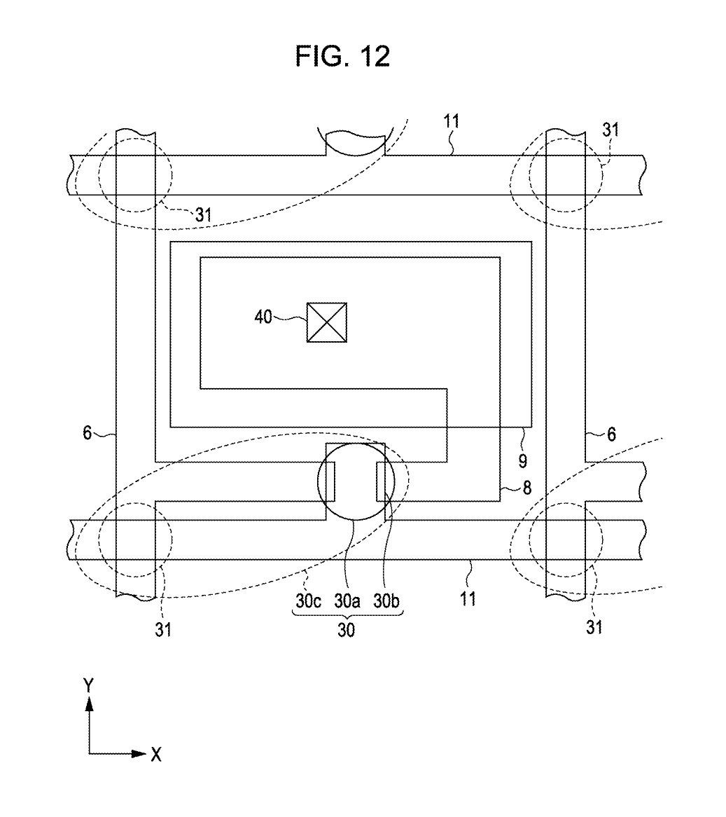

Next, the structure of an electrophoretic display panel according to a sixth embodiment will be described with reference to FIG. 12. The overall structure of the electrophoretic display panel of the sixth embodiment is basically similar to that of the electrophoretic display panel of the embodiments described above. Therefore, a description of points common to the above embodiments is omitted as appropriate, and points different from the above embodiments will be mainly described.

FIG. 12 is an enlarged plan view of a display portion 10a of an electrophoretic display panel 1 according to the sixth embodiment.

Referring to FIG. 12, comparing to the fifth embodiment in which the storage capacitor 70 is not provided, in plan view on an element substrate 10, a gate insulating film 30c in this sixth embodiment is formed so as to extend to regions where an interlayer insulating film 31 is formed. That is, in plan view on the element substrate 10, in the regions where the interlayer insulating film 31 is formed, the gate insulating film 30c is formed on the upper layer side of the interlayer insulating film 31 so as to cover the interlayer insulating film 31. Accordingly, since a large interlayer distance between a data line 6 and a scanning line 11 can be ensured as compared with the first embodiment (that is, since the thickness of the interlayer insulating film 31 in the first embodiment can be substantially increased), a mutual influence of signals between the data line 6 and the scanning line 11 can be more effectively suppressed. As a result, the electrophoretic display panel 1 in which disturbance of image signals is small and which can display high-quality images can be realized.

### Seventh Embodiment

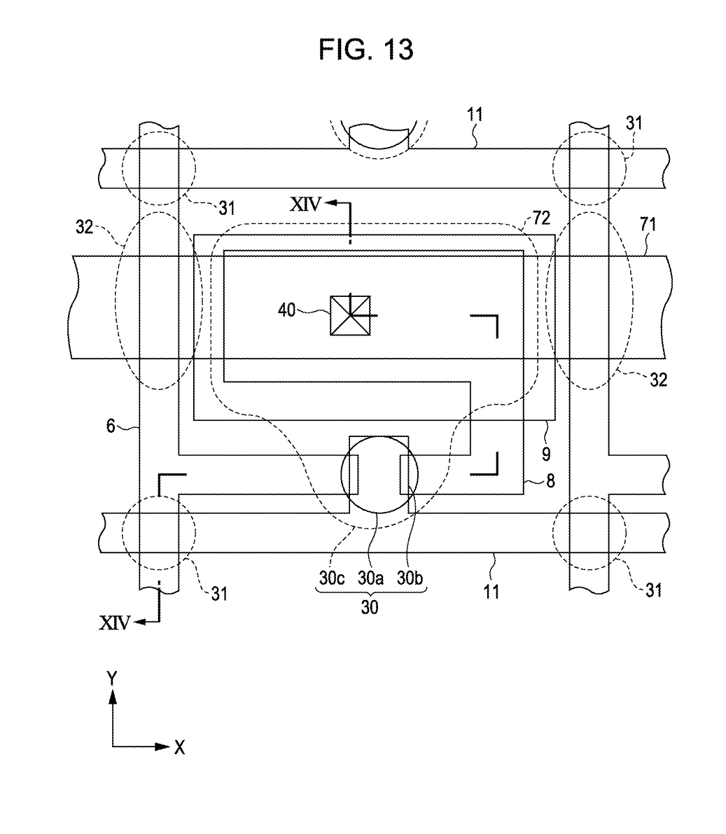

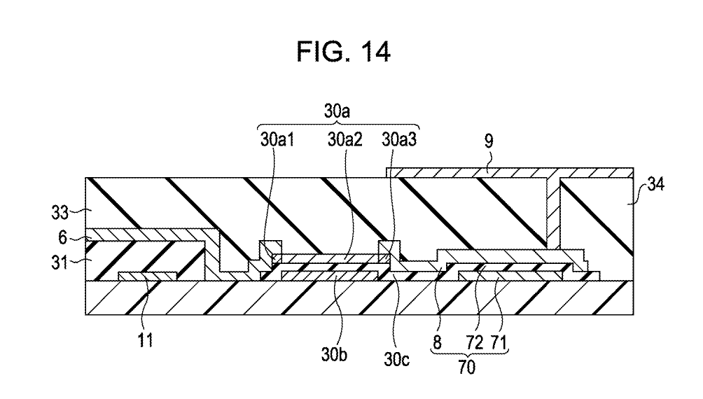

Next, the structure of an electrophoretic display panel according to a seventh embodiment will be described with reference to FIGS. 13 and 14. The overall structure of the electrophoretic display panel of the seventh embodiment is basically similar to that of the electrophoretic display panel of the first embodiment. Therefore, a description of points common to the first embodiment is omitted as appropriate, a point different from the first embodiment will be mainly described.

FIG. 13 is an enlarged plan view of a display portion 10a of the electrophoretic display panel 1 according to the seventh embodiment. FIG. 14 is a cross-sectional view taken along line XIV-XIV of FIG. 13.

Referring to FIGS. 13 and 14, the seventh embodiment differs from the first embodiment in that, in plan view on an element substrate 10, a gate insulating film 30c is formed so as to extend to a wide range on a capacitor electrode 71 and to also function as a capacitor insulating film 72. By forming the gate insulating film 30c in this manner, the capacitor insulating film 72 can be formed at the same time. Accordingly, the number of steps in the production process can be reduced to suppress the production cost.

### Eighth Embodiment

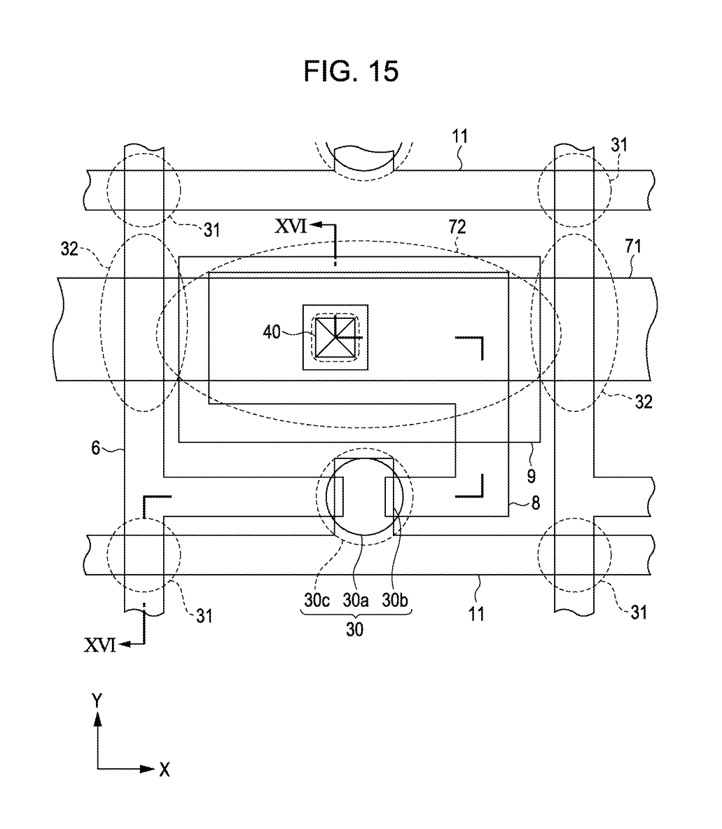

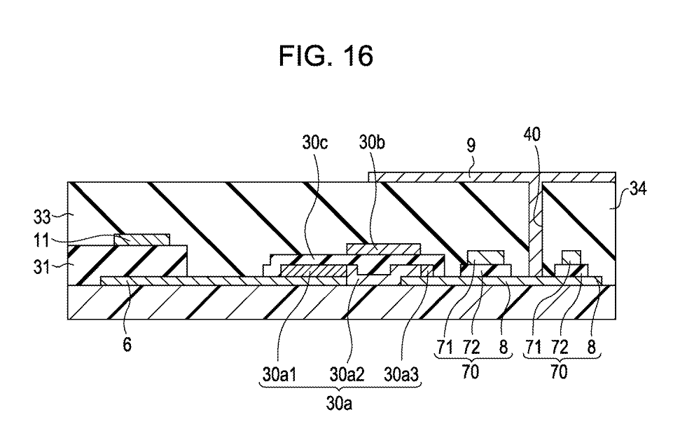

Next, the structure of an electrophoretic display panel according to an eighth embodiment will be described with reference to FIGS. 15 and 16. The overall structure of the electrophoretic display panel of the eighth embodiment is basically similar to that of the electrophoretic display panel of the first embodiment. Therefore, a description of points common to the above embodiments is omitted as appropriate, and points different from the above embodiments will be mainly described.

FIG. 15 is an enlarged plan view of a display portion 10a of an electrophoretic display panel 1 according to the eighth embodiment. FIG. 16 is a cross-sectional view taken along line XVI-XVI of FIG. 15.

In the first to seventh embodiments described above, the TFTs 30 have a bottom-gate structure, whereas TFTs 30 in the eighth embodiment have a top-gate structure.

In FIGS. 15 and 16, a data line 6 and a relay layer 8 are provided on an element substrate 10. The data line 6 and the relay layer 8 are electrically connected to a source region 30a1 and a drain region 30a3, respectively, of a semiconductor layer 30a formed on the upper layer side.

A scanning line 11 is provided on the upper layer side of the data line 6. An interlayer insulating film 31 is provided between the data line 6 and the scanning line 11. In order to effectively suppress the interaction between the data line 6 and the scanning line 11, this interlayer insulating film 31 is preferably formed so as to have a small relative dielectric constant and a large film thickness as in the first embodiment.

A gate electrode 30b is provided on the upper layer side of the semiconductor layer 30a with a gate insulating film 30c therebetween. The gate electrode 30b is formed by a portion branched from the scanning line 11 in plan view, and is formed as substantially the same film as the scanning line 11.

As in the first embodiment, in order to improve the performance of the TFT 30, the gate insulating film 30c is preferably formed so as to have a small thickness within a range in which insulation between the semiconductor layer 30a and the gate electrode 30b is reliably ensured.

A capacitor insulating film 72 is partly provided so that a region where a contact hole 40 is to be formed is ensured on the upper layer side of the relay layer 8. Furthermore, the capacitor electrode 71 is formed on the upper layer side of the capacitor insulating film 72 to form a storage capacitor 70.

Here, as in the first embodiment, the capacitor insulating film 72 is preferably formed so as to have a small thickness using a material having a large relative dielectric constant so that the capacitance of the storage capacitor 70 becomes large.

Interlayer insulating films 33 and 34 are formed on the stacked structure descried above. A pixel electrode 9 is provided on the upper layer side of the interlayer insulating films 33 and 34, and is electrically connected to the relay layer 8 through the contact hole 40.

### Ninth Embodiment

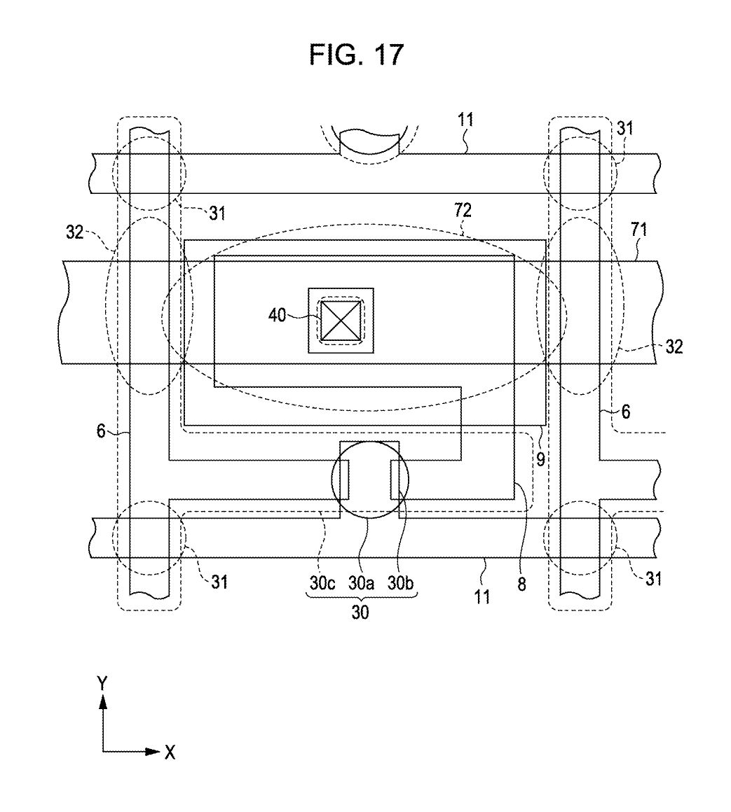

Next, the structure of an electrophoretic display panel according to a ninth embodiment will be described with reference to FIG. 17. The overall structure of the electrophoretic display panel of the ninth embodiment is basically similar to that of the electrophoretic display panel of the above embodiments. Therefore, a description of points common to the above embodiments is omitted as appropriate, and points different from the above embodiments will be mainly described.

FIG. 17 is an enlarged plan view of a display portion 10a of an electrophoretic display panel 1 according to the ninth embodiment.

In the ninth embodiment, TFTs 30 having a top-gate structure are used as in the eighth embodiment. The ninth embodiment differs from the eighth embodiment in that, in plan view on an element substrate 10, a gate insulating film 30c is formed so as to widely extend and mainly overlap with a data line 6.

In regions where a data line 6 and a scanning line 11 are overlapped with each other, the gate insulating film 30c is arranged so as to overlap with an interlayer insulating film 31 in plan view on the element substrate 10. As a result, since a large distance between the data line 6 and the scanning line 11 can be ensured (that is, since this is equivalent to that the thickness of the interlayer insulating film 31 is substantially increased), an interaction between the data line 6 and the scanning line 11 can be effectively suppressed.

Furthermore, in regions where a data line 6 and a capacitor electrode 71 are overlapped with each other, the gate insulating film 30c is arranged so as to overlap with an interlayer insulating film 32 in plan view on the element substrate 10. As a result, since a large distance between the data line 6 and the capacitor electrode 71 can be ensured (that is, since this is equivalent to that the thickness of the interlayer insulating film 32 is substantially increased), a parasitic capacitance between the data line 6 and the capacitor electrode 71 can be further decreased. In addition, it is also possible to prevent short-circuit between the data line 6 and the gate electrode 30b, the scanning line 11, the semiconductor layer 30a, or the like due to a foreign substance or a pattern defect.

### Production Method

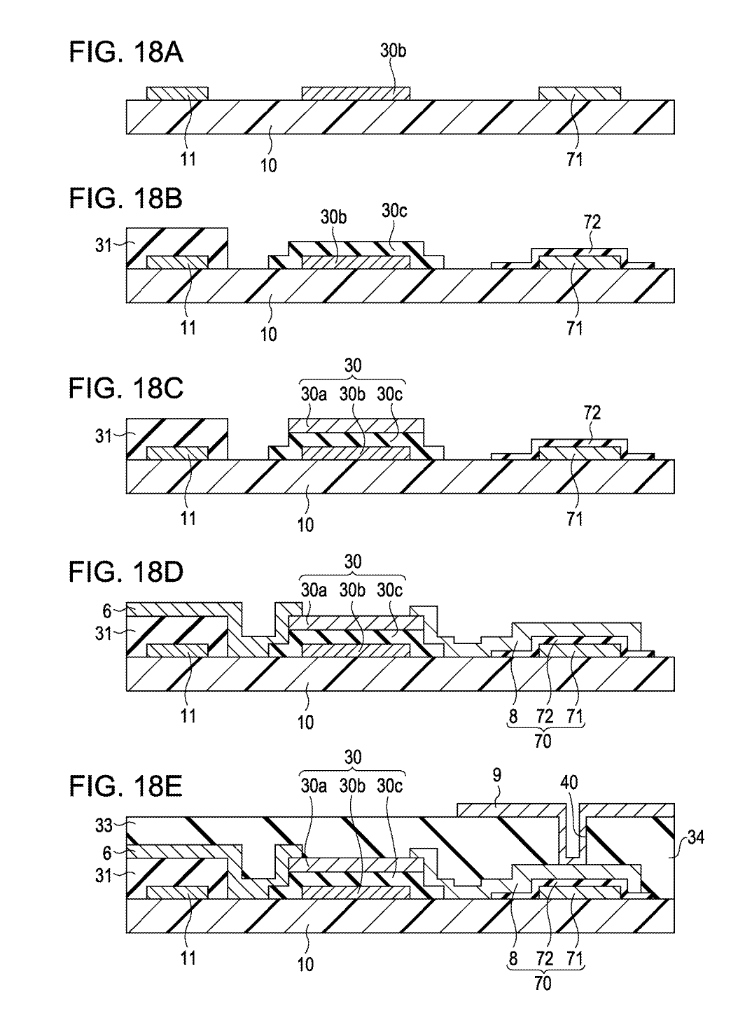

A method for producing an active matrix substrate included in the electrophoretic display panel according to one of the above-described embodiments will now be described with reference to FIGS. 18A to 18E. As described above, the active matrix substrate according to this embodiment includes an element substrate 10 and a stacked structure provided on the element substrate 10.

FIGS. 18A to 18E are process cross-sectional views that illustrate, in order, a method for producing the active matrix substrate according to the first embodiment in correspondence with the cross-sectional view of FIG. 5.

First, as an element substrate 10, a film substrate that is formed using, as a material, a polyethylene terephthalate (PET) film having a thickness of 0.5 mm is prepared. Alternatively, for example, polyethersulfone (PES), polyetherimide, polyetherketone, polyphenylene sulfide, polyarylate, polyimide, polycarbonate (PC), aromatic polyester (liquid crystal polymer), cellulose triacetate (TAC), cellulose acetate propionate (CAP), or the like may also be used as the material of the element substrate 10. Thus, an organic insulating substrate may be used as the element substrate 10. In particular, such an organic insulating substrate is preferably used as the element substrate 10 because the use of the organic insulating substrate can contribute to a reduction in the weight and an improvement in the flexibility of the electrophoretic display panel. Alternatively, an inorganic insulating substrate such as a glass substrate, a silicon substrate, or a thin metal sheet may also be used as the element substrate 10.

Next, a scanning line 11, a capacitor electrode 71, and a gate electrode 30b, all of which are composed of aluminum and have a thickness of 100 nm, are formed on the element substrate 10 (refer to FIG. 18A). Specifically, the scanning line 11, the capacitor electrode 71, and the gate electrode 30b are preferably formed at the same time by, for example, forming an electrically conductive film on the element substrate 10 in a solid manner by a sputtering method or the like, and patterning the electrically conductive film.

The method for forming the scanning line 11 may be, for example, a sputtering method, an evaporation method, or an ink jet method. Alternatively, a printing method such as a screen printing method, an offset printing method, a gravure printing method, or a microcontact printing method may also be employed.

The material of the scanning line 11, the capacitor electrode 71, and the gate electrode 30b is an electrically conductive material such as aluminum (Al), tungsten (W), titanium (Ti), or titanium nitride (TiN). The film thickness of the scanning line 11, the capacitor electrode 71, and the gate electrode 30b is preferably about 100 nm, but is not limited thereto.

Subsequently, an interlayer insulating film 31 composed of an acrylic resin and having a thickness of 1 μm, a capacitor insulating film 72 composed of a polyimide resin and having a thickness of 0.3 μm, and a gate insulating film 30c composed of a polyamide resin and having a thickness of 0.2 μm are sequentially formed by an application method such as an ink jet method on the element substrate 10 on which the scanning line 11, the capacitor electrode 71, and the gate electrode 30b have been formed (refer to FIG. 18B). As a method for forming these insulating films, any method with which a film can be partially formed in a specific region may be employed. Examples of the method include printing methods such as a screen printing method, an offset printing method, and a gravure printing method; wet methods, such as a bar-coating method and a spray method, with which an insulating film can be partially formed in a specific region; and a method of applying a film-formation gas to a specific region. That is, these methods for forming an insulating film are not particularly limited as long as an insulating film can be directly formed in a region on the element substrate 10 finally.

When the insulating films are formed on the element substrate 10 using any of these methods, deflection (i.e., structural distortion) of the final active matrix substrate can be effectively suppressed as compared with the case where such insulating films are formed by patterning a single insulating film formed over the entire surface of a substrate.

In addition, by employing any of these methods for forming insulating films, the amount of material necessary for forming the insulating films can be suppressed to be small. Specifically, when the insulating films are formed by patterning, it is necessary to form an insulating film on the element substrate 10 in a solid manner. Therefore, a part of the insulating film removed by the patterning is wasted. In contrast, in the above method used in this embodiment, the insulating films can be directly formed only in regions where the insulating films should be formed. Therefore, in forming the insulating films, there is no portion where the film material is wasted. Accordingly, the amount of material necessary for forming the insulating films can be minimized, and thus an active matrix substrate that meets the requirements of resource saving and a low cost can be produced.

In this step, the gate insulating film 30c is preferably formed after the formation of the interlayer insulating film 31 and the capacitor insulating film 72. If the gate insulating film 30c is formed before the formation of the interlayer insulating film 31 and the capacitor insulating film 72, the surface of the previously formed gate insulating film 30c may be contaminated or broken by various solutions and the like used in the formation of the interlayer insulating film 31 and the capacitor insulating film 72. On the upper surface of the gate insulating film 30c, a semiconductor layer 30a is formed, thereby constituting a TFT 30. Accordingly, if the surface of the gate insulating film 30c is contaminated or broken, the performance of the TFT 30 may be degraded. For this reason, in this embodiment, by forming the gate insulating film 30c after the formation of the interlayer insulating film 31 and the capacitor insulating film 72, a TFT 30 having a satisfactory performance can be formed.

The step of forming the interlayer insulating film 31, the capacitor insulating film 72, and the gate insulating film 30c is preferably performed, for example, in a chamber filled with nitrogen (N₂) or in an atmosphere of reduced pressure. By forming the insulating films in such an environment, it is possible to effectively prevent impurities such as oxygen, moisture, and the like, and an inert gas from being mixed in the insulating films.

The interlayer insulating film 31 is preferably formed using a material having a small relative dielectric constant so as to have a large thickness. When the interlayer insulating film 31 is formed in such a manner, the capacitance of a capacitor that is substantially formed by a data line 6 and a scanning line 11, which serve as a pair of electrodes, can be suppressed to be small. Thus, an interaction generated between the scanning line 11 and the data line 6 can be effectively suppressed. Specifically, the interlayer insulating film 31 may be formed using an acrylic resin having a relative dielectric constant of about 3.3 as a material so as to have a thickness in the range of 20 nm to 100 μm.

The capacitor insulating film 72 is preferably formed so as to have a large relative dielectric constant and a small thickness. By forming the capacitor insulating film 72 in such a manner, a large capacitance of a storage capacitor 70 can be ensured to improve the storage property of the TFT 30. Specifically, a sufficient capacitance can be ensured by forming the capacitor insulating film 72 having a thickness of about 0.3 μm using a polyimide resin having a relative dielectric constant of about 3.6 as a material. In consideration of design factors such as the dielectric constant, the film thickness may be in the range of 10 nm to 1 μm. The gate insulating film 30c is preferably formed so as to have a small thickness using a material having a large relative dielectric constant from the standpoint of improving the performance of the TFT 30. Therefore, the film thickness of the gate insulating film 30c is preferably as small as possible, but is preferably determined within a range in which electrical insulation between the semiconductor layer 30a and the gate electrode 30b can be reliably ensured. By determining the film thickness of the gate insulating film 30c in this manner, both an improvement in the performance of the TFT 30 and high reliability thereof can be achieved. Specifically, the film thickness of the gate insulating film 30c is preferably determined in the range of about 10 nm to 1 μm.

Subsequently, after the formation of the gate insulating film 30c, a semiconductor layer 30a composed of pentacene and having a thickness of 50 nm is formed on the gate insulating film 30c successively (specifically, without conducting other steps therebetween) (refer to FIG. 18C). If other steps (for example, a step of forming a data line 6 and a step of forming a relay layer 8) are conducted between the step of forming the gate insulating film 30c and the step of forming the semiconductor layer 30a, the surface of the gate insulating film 30c may be contaminated or broken by a solution or the like used in the other steps. As described above, if the surface of the gate insulating film 30c is contaminated, the performance of the TFT 30 is degraded. In this embodiment, by successively forming the semiconductor layer 30a after the formation of the gate insulating film 30c, a TFT 30 having a satisfactory performance can be formed.

Methods similar to those used in the formation of the gate insulating film 30c or the scanning lines 11 can be employed as a method for forming the semiconductor layer 30a.

Next, a data line 6 and a relay layer 8 composed of gold and having a thickness of 100 nm are formed (refer to FIG. 18D). The data line 6 and the relay layer 8 are preferably formed at the same time by, for example, forming an electrically conducting film on the element substrate 10, and patterning the electrically conductive film.

It is known that when an organic semiconductor material such as pentacene is used as a semiconductor layer, in general, the source region 30a1 and the drain region 30a3 are naturally formed in the semiconductor layer 30a that contacts the data line 6 and the relay layer 8, respectively. Introduction of an impurity or the like need not be performed. It is believed that this is because when the Fermi levels of a carrier of a semiconductor material and a carrier of a metal substantially coincide with each other, electric charges naturally flow.

Examples of the material of the data line 6 and the relay layer 8 include metals such as aluminum (Al), tungsten (W), titanium (Ti), and titanium nitride (TiN); and organic electrically conductive materials.

Subsequently, interlayer insulating films 33 and 34 composed of an acrylic resin and having a thickness of 1 μm are formed at the same time so that a contact hole 40 is opened (refer to FIG. 18E). A photosensitive acrylic resin is applied by a spin-coating method, and the resulting film is exposed and developed to form the contact hole. Here, the interlayer insulating films 33 and 34 may be directly formed on the element substrate 10 (that is, only on the regions shown in FIG. 18E in a limited manner) using a printing technique other than spin coating. In this case, the contact hole is naturally formed by the method that does not include a step of applying the material of the interlayer insulating films. The contact hole 40 may be formed by forming an insulating film over the entire surface of the element substrate 10 and etching the insulating film. However, it should be noted that when such a method is employed, it is necessary to use various solutions during the etching or the like, thereby increasing a risk of generating contamination or breakage in the resulting stacked structure.

A pixel electrode 9 composed of ITO and having a thickness of 50 nm is formed on the interlayer insulating films 33 and 34 (refer to FIG. 18E). Examples of the material of the pixel electrode 9 that can be used include various electrically conductive materials such as aluminum and ITO.

FIGS. 18A to 18E show a method for producing the active matrix substrate of the first embodiment. The active matrix substrates of the second to seventh embodiments can also be produced by substantially the same method.

In the eighth and ninth embodiments, unlike the above bottom-gate structure, TFTs having a top-gate structure are used. A production method in this case corresponds to a method in which the step of forming the gate electrode 30b in FIG. 18A and the step of forming the data line 6 and the relay layer 8 in FIG. 18D are interchanged. After the interlayer insulating film 31 and the capacitor insulating film 72 are formed, the semiconductor layer 30a and the gate insulating film 30c are successively formed.

In this case, the film thicknesses and the materials of the respective films may be similar to those in the first embodiment.

Each of the active matrix substrates according to these embodiments can be produced by forming a stacked structure on the element substrate 10 through the steps described above.

### Electronic Apparatus

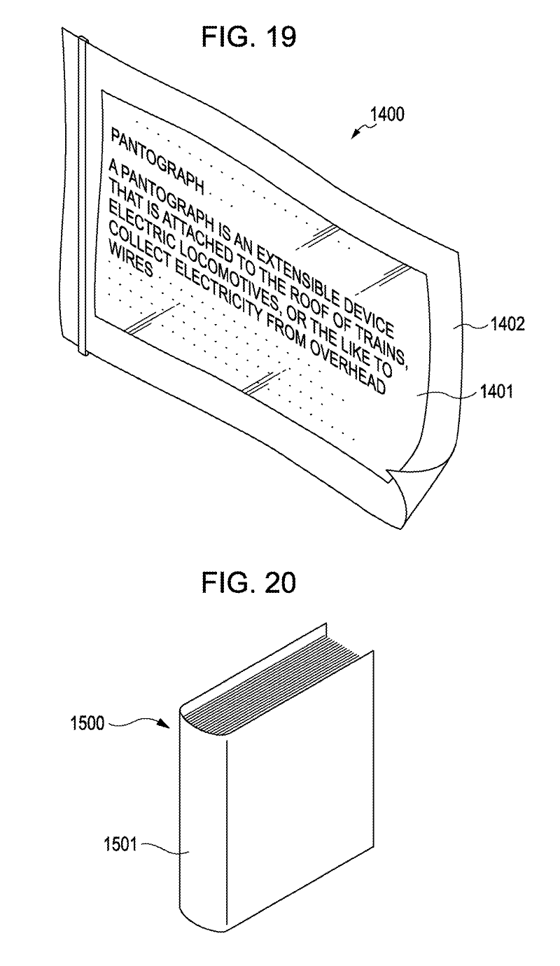

Next, electronic apparatuses to which the electrophoretic display device described above is applied will be described with reference to FIGS. 19 and 20. Cases where the above-described electrophoretic display device is applied to an electronic paper sheet and an electronic notebook will now be described as examples.

FIG. 19 is a perspective view showing the structure of an electronic paper sheet 1400.

As shown in FIG. 19, the electronic paper sheet 1400 includes the electrophoretic display device according to any of the above embodiments as a display portion 1401. The electronic paper sheet 1400 has flexibility and is configured to include a main body 1402 composed of a rewritable sheet having a texture and flexibility similar to those of normal paper.

FIG. 20 is a perspective view showing the structure of an electronic notebook 1500.

As shown in FIG. 20, the electronic notebook 1500 is produced by binding a plurality of the electronic paper sheets 1400 shown in FIG. 19 so as to be inserted into a cover 1501. The cover 1501 includes a display data inputting unit (not shown) that receives display data transmitted from an external device, for example. Accordingly, the display content can be changed or updated in accordance with the display data in a state in which the electronic paper sheets are bound.

The above-described electronic paper sheet 1400 and the electronic notebook 1500 each include the electrophoretic display device according to any of the above embodiments. Therefore, high-quality images can be displayed with low electric power consumption.

Furthermore, the electrophoretic display device according to any of the above embodiments can be used as a display portion of an electronic apparatus such as a wrist watch, a cellular phone, or a mobile audio apparatus other than the electronic paper sheet and the electronic notebook.

The invention can also be applied to liquid crystal displays (LCDs), plasma displays (PDPs), field-emission displays (FEDs and SEDs), organic EL displays, digital micromirror devices (DMDs), electrochromic displays, electrowetting displays, and the like besides the electrophoretic display panels described in the above embodiments.

The invention is not limited to the above-described embodiments and can be appropriately changed within the scope not departing from the gist or the idea of the invention that is read out from the claims and the entire specification. A substrate for a semiconductor device, a semiconductor device, and an electronic apparatus that involve such changes also belong to the technical scope of the invention.

The entire disclosure of Japanese Patent Application No. 2009-259951, filed Nov. 13, 2009 is expressly incorporated by reference herein.

What is claimed is:

1. A substrate for a semiconductor device, the substrate comprising:
a substrate;
a transistor disposed on the substrate and including a semiconductor layer, a first insulating film provided in the form of islands so as to at least partly overlap with the semiconductor layer in plan view on the substrate, and a gate electrode disposed so as to face the semiconductor layer with the first insulating film therebetween; and
a second insulating film that is disposed on the substrate as substantially the same film as the first insulating film and that is formed in the form of islands so that at least one of the material and the thickness of the second insulating film is different from that of the first insulating film.

2. The substrate according to claim 1, further comprising:
a pair of capacitor electrodes disposed so as to face each other with the second insulating film therebetween.

3. The substrate according to claim 1, further comprising:
a data line that is electrically connected to the semiconductor layer; and
a gate line that intersects with the data line and that is electrically connected to the gate electrode,
wherein the second insulating film is provided between the data line and the gate line.

4. The substrate according to claim 2, further comprising:
a data line that is electrically connected to the semiconductor layer;
a third insulating film that is disposed as substantially the same film as the first insulating film and the second insulating film and that is formed in the form of islands so that at least one of the material and the thickness of the third insulating film is different from that of at least one of the first insulating film and the second insulating film; and
a gate line that is disposed so as to face the data line with the third insulating film therebetween, that intersects with the data line, and that is electrically connected to the gate electrode.

5. A method for producing a substrate for a semiconductor device, the substrate including a substrate and a transistor provided on the substrate and including a semiconductor layer, a first insulating film, and a gate electrode, the method comprising:
forming the semiconductor layer;
forming the first insulating film in the form of islands so as to at least partly overlap with the semiconductor layer in plan view on the substrate;
forming the gate electrode so as to face the semiconductor layer with the first insulating film therebetween; and
forming a second insulating film as substantially the same film as the first insulating film in the form of islands so that at least one of the material and the thickness of the second insulating film is different from that of the first insulating film.

6. The method according to claim 5,
wherein the first insulating film is formed by applying an insulating material on the substrate in a region where the first insulating film is to be formed, and
the second insulating film is formed by applying an insulating material on the substrate in a region where the second insulating film is to be formed.

7. A semiconductor device comprising:
the substrate according to any one of claims 1 to 4.

8. An electronic apparatus comprising:
the semiconductor device according to claim 7.
